(19) United States
(12) Patent Application Publication
(10) Pub. No.: US 2017/0148726 A1
(43) Pub. Date: May 25, 2017

(54) SEMICONDUCTOR PROCESSING METHOD AND SEMICONDUCTOR DEVICE

(71) Applicant: Applied Materials, Inc., Santa Clara, CA (US)

(72) Inventors: Stephen MOFFATT, St. Brelade (JE); Abhilash J. MAYUR, Salinas, CA (US); Theodore P. MOFFITT, Hillsboro, OR (US); Aaron Muir HUNTER, Santa Cruz, CA (US); Shashank SHARMA, Fremont, CA (US); Bruce E. ADAMS, Portland, OR (US); Samuel C. HOWELLS, Portland, OR (US); Douglas E. HOLMGREN, Portland, OR (US); Wolfgang R. ADERHOLD, Cupertino, CA (US)

(21) Appl. No.: 15/341,896

(22) Filed: Nov. 2, 2016

Related U.S. Application Data
(60) Provisional application No. 62/250,004, filed on Nov. 3, 2015.

(51) Int. Cl. H01L 23/528; H01L 23/532; H01L 21/762; H01L 21/268

(52) U.S. Cl. CPC H01L 23/528; H01L 21/268; H01L 23/53209; H01L 21/762

(57) ABSTRACT

A semiconductor processing method and semiconductor device are described. The processing method includes forming a p-doped germanium structure on a substrate, annealing the p-doped germanium structure using pulses of laser radiation, and forming a titanium structure in direct contact with the p-doped germanium structure.

### CROSS-REFERENCE TO RELATED APPLICATIONS

This application claims benefit of U.S. Provisional Patent Application Ser. No. 62/250,004, filed Nov. 3, 2015, which is incorporated herein by reference.

### FIELD

Embodiments of the present disclosure generally relate to advanced transistor structures, such as source-drain layers and contacts.

### BACKGROUND

Due to its superior hole mobility, p-type Ge is an attractive channel material for pMOSFETs. The small-dimension p-Ge FinFETs has been successfully integrated onto 300 mm Si wafers. With the shrinking device and contact dimension, the metal/semiconductor contact resistivity (ρ_{c}) becomes increasingly influential. However, only a few ρ_{c} studies on the p-Ge have been reported, which usually use deep p⁺/n Ge junctions and thus cannot be directly referred to for the downscaled devices. Therefore, device-oriented investigations on the p-Ge contacts are urgently required.

Till this moment, NiGe has been most frequently used as the source/drain contact metal for p-Ge transistors. However, unlike NiSi, NiGe has a low thermal stability: the agglomeration of NiGe starts at only 500° C. , and Ge voids could form during the germanidation. Therefore, better contact structures are called for in germanium-based semiconductor devices.

### SUMMARY

Embodiments of the present disclosure provide a method of processing a substrate, comprising forming a germanium structure on a substrate by epitaxy; doping the germanium structure with a p-type dopant to form a doped germanium structure; forming an annealed structure by delivering one or more laser pulses to each of a plurality of target zones of the doped germanium structure; and forming a titanium structure on the annealed structure.

Also disclosed is a method of processing a substrate, comprising forming a p-doped epitaxial germanium structure on a substrate; and forming a titanium structure on the p-doped epitaxial germanium structure.

Also disclosed is a method of processing a substrate, comprising forming a germanium structure on a substrate; implanting the germanium structure with ions of a p-type dopant at a temperature between about 200K and about 300 K; forming an annealed structure by delivering one or more laser pulses to each of a plurality of target zones of the doped germanium structure; and forming a titanium structure on the annealed structure.

Also disclosed is a semiconductor device, comprising an activated p-doped epitaxial germanium structure; and a titanium structure in direct contact with the activated p-doped epitaxial germanium structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic diagram of a laser processing system that may be used for the laser processing described herein.

FIG. 2A is a graph showing contact resistivity of various samples processed according to methods described herein.

FIG. 2B is a graph showing contact resistances and sheet resistances of the samples of FIG. 2A.

FIGS. 3A and 3B are graphs of Fin-TLM resistance versus electrode spacing for the samples of FIG. 2A.

FIGS. 4A-4D are graphs showing CTLM data for NiGe/p-Ge samples processed by comparative methods.

FIG. 4E is a schematic cross-sectional view of a device processed according to a comparative method.

FIG. 5 is a graph showing doping profile of the samples of FIG. 2A prior to annealing.

FIG. 6 is a scatter plot of results according to methods described herein along with comparative results.

### DETAILED DESCRIPTION

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a basis plane of the chamber, for example a plane parallel to a substrate processing surface of the chamber.

In this work, with both a planar circular transmission line model (CTLM) and a fin based transmission line model (Fin-TLM), we compare NiGe/p-Ge and Ti/p-Ge contacts in terms of the ρ_{c} and the thermal stability. We find that the NiGe based devices suffer from a thermally driven short circuit problem, while the Ti contacts show low ρ_{c} and an adequate stability. Therefore, the Ti contact is a better candidate for p-Ge devices. In this disclosure, the ρ_{c} of Ti/p-Ge has been reduced to 1.1×10⁻⁸ Ω·cm² using a multi-pulse laser technique. The Ti/p-Ge contacts show low contact resistance, while the NiGe/p-Ge devices show short circuit problems due to the thermally driven Ni diffusion. Considering the thermal budget in the backend of line manufacturing process, the Ti contact is more suitable for Ge p-devices. A low Ti/p-Ge contact resistivity of 1.1×10⁻Ω·cm² is achieved by using a multi-pulse laser anneal technique for the B activation. The multi-pulse laser anneal technique includes annealing portions of the substrate by exposing all areas of the annealed portions to multiple pulses of laser radiation.

### Experiments

The CTLM structures were fabricated on 300 mm Si wafers. 600 nm thick epitaxial Ge was grown. A P-well was formed. A 5 KeV 1×10¹⁵ cm⁻² Ge preamorphization implantation (PAI) was performed, followed by a 1.6 KeV 1×10¹⁵ cm⁻² B ion implantation (I/I). B was activated with either a 600° C. 5 min rapid thermal process (RTP) in N₂ or a laser anneal. The laser anneal was performed by a Laser Thermal Processing tool from Applied Materials, which can provide a controlled laser energy fluence with a pulse width of tens of nanoseconds. Both single-pulse (SP) and multi-pulse (MP) laser were compared. The details of the rest of the CTLM patterning process can be found elsewhere. For Ti/p-Ge samples, 5 nm PVD Ti was deposited on p⁺-Ge. For NiGe/p-Ge samples, 10 nm PVD Ni was deposited; and NiGe was formed by a 290° C. 30 s RTP, a selective wet etch, and a 355° C. 30 s RTP.

The Fin-TLMs started with an Ge epitaxy in 100 nm wide Si STI trenches. A P well was formed. The Ge PAI, B I/I, RTP activation, and the contact metal formation process were identical to those used for CTLM. The Fin-TLMs were interconnected with CVD W. A standard H₂ sintering for 20 min was carried out at the end of the Fin-TLM process.

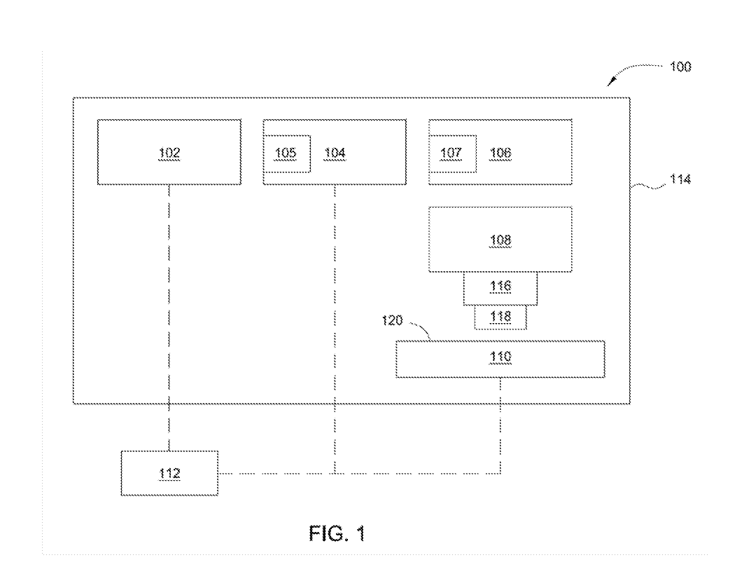

FIG. 1 is a schematic diagram of a laser processing system 100 that may be used for the laser processing described herein. The system 100 comprises an energy module 102 that has a plurality of pulsed laser sources producing a plurality of pulsed laser pulses, a pulse control module 104 that combines individual pulsed laser pulses into combination pulsed laser pulses, and that controls intensity, frequency characteristics, and polarity characteristics of the combination pulsed laser pulses, a pulse shaping module 106 that adjusts the temporal profile of the pulses of the combined pulsed laser pulses, a homogenizer 108 that adjusts the spatial energy distribution of the pulses, overlapping the combination pulsed laser pulses into a single uniform energy field, an aperture member 116 that removes residual edge non-uniformity from the energy field, and an alignment module 118 that allows precision alignment of the laser energy field with a substrate disposed on a substrate support 110. A controller 112 is coupled to the energy module 102 to control production of the laser pulses, the pulse control module 104 to control pulse characteristics, and the substrate support 110 to control movement of the substrate with respect to the energy field. An enclosure 114 typically encloses the operative components of the system 100.

The lasers may be any type of laser capable of forming short pulses, for example duration less than about 100 nsec, of high power laser radiation. Typically, high modality lasers having over 500 spatial modes with M² greater than about 30 are used. Solid state lasers such as Nd:YAG, Nd:glass, titanium-sapphire, or other rare earth doped crystal lasers are frequently used, but gas lasers such as excimer lasers, for example XeCl₂, ArF, or KrF lasers, may be used. The lasers may be switched, for example by q-switching (passive or active), gain switching, or mode locking. A Pockels cell may also be used proximate the output of a laser to form pulses by interrupting a beam emitted by the laser. In general, lasers usable for pulsed laser processing are capable of producing pulses of laser radiation having energy content between about 100 mJ and about 10 J with duration between about 1 nsec and about 100 psec, typically about 1 J in about 8 nsec. The lasers may have wavelength between about 200 nm and about 2,000 nm, such as between about 400 nm and about 1,000 nm, for example about 532 nm. In one embodiment, the lasers are q-switched frequency-doubled Nd:YAG lasers. The lasers may all operate at the same wavelength, or one or more of the lasers may operate at different wavelengths from the other lasers in the energy module 102. The lasers may be amplified to develop the power levels desired. In most cases, the amplification medium will be the same or similar composition to the lasing medium. Each individual laser pulse is usually amplified by itself, but in some embodiments, all laser pulses may be amplified after combining.

A typical laser pulse delivered to a substrate is a combination of multiple laser pulses. The multiple pulses are generated at controlled times and in controlled relationship to each other such that, when combined, a single pulse of laser radiation results that has a controlled temporal and spatial energy profile, with a controlled energy rise, duration, and decay, and a controlled spatial distribution of energy non-uniformity. The controller 112 may have a pulse generator, for example an electronic timer coupled to a voltage source, that is coupled to each laser, for example each switch of each laser, to control generation of pulses from each laser.

The plurality of lasers are arranged so that each laser produces pulses that emerge into the pulse control module 104, which may have one or more pulse controllers 105. The pulse controllers may employ rotatable wave plates with polarizing filters to attenuate the intensity of the pulses admitted through the pulse controllers. Individual pulse trains may be subjected to attenuation through an A-direction filter or a B-direction filter, where direction B is orthogonal to direction A, and may also be directed to opposite planes of a polarizing filter oriented in the A or B direction to combine the pulse trains along a single optical axis. Sensors may sample the resulting pulse train for power and/or energy content, the results of which may be used to adjust the pulse controllers. Wavelength selection may also be used instead of, or in addition to, polarization selection for attenuation and/or combining.

The pulses, potentially combined to a single optical axis, exit the pulse controllers 105 and enter the pulse shaping module 106, which has one or more pulse shapers 107. The pulse shapers 107 generally divide the pulses and/or pulse train(s) into units of radiation and send each unit of radiation along a path having a different length. The difference in path length between two radiation units is typically longer than a coherence length of the radiation, so the pulse shapers 107 reduce correlation of the radiation. The pulse shapers 107 may include beam splitters and mirrors to divide, decorrelate, and recombine the radiation units. Alternately fiber bundles with different fiber lengths, refractive members with different thickness regions or different materials having different refractive indices, beam deflectors and interrupters, diffusion members, and the like may also be used. The pulse shapers 107 generally lengthen radiation pulses, and may also change the temporal profile of a pulse, for example from a natural Gaussian profile to a trapezoidal shape with substantially linear power onset, substantially constant pulse delivery, and substantially linear power decay.

Shaped pulses from the pulse shaping module 106 are routed into a homogenizer 108. The homogenizer 108 may include refractive, diffractive, diffusive, and reflective elements. In one embodiment, the homogenizer 108 includes two microlens arrays, a first microlens array receiving radiation from the pulse shaping module 106 and delivering spatially decorrelated radiation to the second microlens array. The homogenizer 108 generally reduces spatial correlation of the radiation. The pulse shaping module 106 and the homogenizer 108 together transform the incident radiation field from a TEM_{xy} distribution, where x and y are defined by characteristics of the lasers, and may both be zero, to a substantially uniform radiation field having cross-sectional power distribution that varies less than 30% from an average value.

Energy from the homogenizer 108 is typically arranged in a pattern, such as a square or rectangular shape, that approximately fits an area to be annealed on the surface of a substrate. The processing and rearranging applied to the energy results in an energy field having intensity that varies from an average value by no more than about 15%, such as less than about 12%, for example less than about 8%. Near the edges of the energy field, however, more significant non-uniformities may persist due to various boundary conditions throughout the apparatus. These edge non-uniformities may be removed using an aperture member 116. The aperture member 116 is typically an opaque object having an opening through which the energy may pass in cross-section shaped like the opening.

An imaging optic 118 receives the shaped, smoothed, and truncated energy field from the aperture member 116 and projects it onto a substrate disposed on a work surface 120 of the substrate support 110.

Thermal energy is coupled into a substrate disposed on a work surface of a substrate support using methods disclosed herein. The thermal energy is developed by applying electromagnetic energy at an average intensity between about 0.2 J/cm² and about 1.0 J/cm² to successive portions of the surface of a substrate in short pulses of duration between about 1 nsec and about 100 nsec, such as between about 5 nsec and about 50 nsec, for example about 10 nsec. A plurality of such pulses may be applied to each portion of the substrate, with a duration between the pulses of 50 msec or more, such as 50-500 msec, for example about 200 msec or 400 msec, to allow complete dissipation of the thermal energy through the substrate before the next pulse arrives. The energy field typically covers an area of between about 0.1 cm² and about 10.0 cm², for example about 6 cm², resulting in a power delivery of between about 0.2 MW and about 10 GW with each pulse. In most applications, the power delivered with each pulse will be between about 10 MW and about 500 MW. The power density delivered is typically between about 2 MW/cm² and about 1 GW/cm², such as between about 5 MW/cm² and about 100 MW/cm², for example about 10 MW/cm². The energy field applied in each pulse has spatial standard deviation of intensity that is no more than about 4%, such as less than about 3.5%, for example less than about 3.0%, of the average intensity.

Delivery of the high power and uniformity energy field mostly desired for annealing of substrates may be accomplished using an energy source 102 with a plurality of lasers emitting radiation readily absorbed by the substrate to be annealed. In one aspect, laser radiation having a wavelength of about 532 nm is used, based on a plurality of frequency-doubled Nd:YAG lasers. Four such lasers having individual power output about 50 MW may be used together for suitable annealing of a silicon substrate.

Pulses of energy may be formed by interrupting generation or propagation of a beam of energy. A beam of energy may be interrupted by disposing a fast shutter across an optical path of the beam. The shutter may be an LCD cell capable of changing from transparent to reflective in 10 nsec or less on application of a voltage. The shutter may also be a rotating perforated plate wherein size and spacing of the perforations are coupled with a selected rate of rotation to transmit energy pulses having a chosen duration through the openings. Such a device may be attached to the energy source itself or spaced apart from the energy source. An active or passive q-switch, or a gain switch may be used. A Pockels cell may also be positioned proximate to a laser to form pulses by interrupting a beam of laser light emitted by the laser. Multiple pulse generators may be coupled to an energy source to form periodic sequences of pulses having different durations, if desired. For example, a q-switch may be applied to a laser source and a rotating shutter having a periodicity similar to that of the q-switch may be positioned across the optical path of the pulses generated by the q-switched laser to form a periodic pattern of pulses having different durations.

Self-correlation of the pulses is reduced by increasing the number of spatial and temporal modes of the pulses. Correlation, either spatial or temporal, is the extent to which different photons are related in phase. If two photons of the same wavelength are propagating through space in the same direction and their electric field vectors point the same direction at the same time, those photons are temporally correlated, regardless of their spatial relationship. If the two photons (or their electric field vectors) are located at the same point in a plane perpendicular to the direction of propagation, those two photons are spatially correlated, regardless of any temporal phase relationship.

Correlation is related to coherence, and the terms are used almost interchangeably. Correlation of photons gives rise to interference patterns that reduce uniformity of the energy field. Coherence length is defined as a distance beyond which coherence or correlation, spatial or temporal, falls below some threshold value.

Photons in pulses can be temporally decorrelated by splitting a pulse into a number of sub-pulses using a succession of splitters, and routing each sub-pulse along a different path with a different optical path length, such that the difference between any two optical path lengths is greater than a coherence length of the original pulse. This largely ensures that initially correlated photons likely have different phase after the different path lengths due to the natural decline in coherence with distance travelled. For example, Nd:YAG lasers and Ti:sapphire lasers typically generate pulses having a coherence length of the order of a few millimeters. Dividing such pulses and sending parts of each pulse along paths having length differences more than a few millimeters will result in temporal decorrelation. Sending sub-pulses along multi-reflective paths with different lengths is one technique that may be used. Send sub-pulses along multi-refractive paths with different effective lengths defined by different refractive indices is another technique.

Spatial decorrelation may be achieved by creating an energy field from a pulse and overlapping portions of the energy field. For example, portions of an energy field may be separately imaged onto the same area to form a spatially decorrelated image. This largely ensures that any initially correlated photons are spatially separated. In one example, a square energy field may be divided into a checkerboard-style 8×8 sampling of square portions, and each square portion imaged onto a field the same size as the original energy field such that all the images overlap. A higher number of overlapping images decorrelates the energy more, resulting in a more uniform image.

A laser pulse imaged after the decorrelation operations described above generally has a cross-section with a uniform energy intensity. Depending on the exact embodiment, the cross-sectional energy intensity of a pulsed energy field treated according to the above processes may have a standard deviation of about 3.0% or less, such as about 2.7% or less, for example about 2.5%. An edge region of the energy field will exhibit a decaying energy intensity that may decay by 1/e along a dimension that is less than about 10% of a dimension of the energy field, such as less than about 5% of the dimension of the energy field, for example less than about 1% of the energy field. The edge region may be truncated using an aperture, as described above, or may be allowed to illuminate a substrate outside a treatment zone, for example in a kurf space between device areas on a substrate.

If the energy field is truncated, an aperture member is typically positioned across the optical path of the pulses to trim the non-uniform edge regions. To achieve clean truncation of the image, the aperture is located near a focal plane of the energy field. Refractive effects of the aperture interior edge may be minimized by tapering the aperture interior edge to match a direction of propagation of photons in the pulse. Multiple removable aperture members having different aperture sizes and shapes may be used to change the size and/or shape of the aperture by inserting or removing the aperture member having the desired size and/or shape. Alternately, a variable aperture member may be used.

An energy field may be directed toward a portion of a substrate to anneal the substrate. The energy field may be aligned, if desired, with structures such as alignment marks on the substrate surface by viewing the substrate surface along the optical path of the energy field. Reflected light from the substrate may be captured and directed toward a viewing device, such as a camera or CCD matrix.

### Titanium or Nice for P-GE?

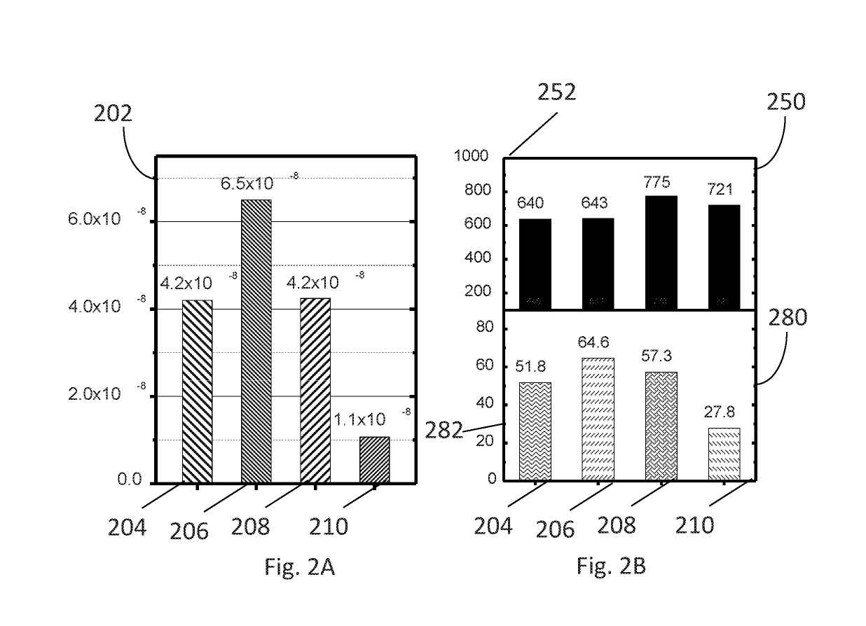

In FIGS. 2A and 2B, Ti/p-Ge and NiGe/p-Ge contacts are compared on CTLM (the laser annealed samples will be discussed in the next section). FIG. 2A shows contact resistivity ρ_{c} (Ω-cm²) along axis 202 for NiGe samples annealed using RTA at 204, Ti/p-Ge samples annealed using RTA at 206, Ti/p-Ge samples annealed using SP laser at 208, and T/p-Ge samples annealed using MP laser at 210. Despite the large work function difference between Ti (˜4.3 eV) and NiGe (˜5.2 eV), the ρ_{c} of the Ti/p-Ge is only slightly higher than that of NiGe/p-Ge. This is because of the strong fermi level pinning at the Ge surface that induces a generally low Schottky barrier height on the p-Ge. As a result, the p_{c} of metal/p-Ge is insensitive to the species of the contact metal. FIG. 2B shows contact resistances R_{c} in graph 250 and sheet resistance Rₛₕ in graph 280. The contact resistances, R_{c}, are shown along axis 252 for the same samples as in FIG. 2A, and the sheet resistances Rₛₕ along axis 282. When the contact length is much larger than the transfer length, the R_{c} and ρ_{c} are correlated by

R_{c}=\sqrt{ρ_{c}Rₛₕ} (1)

where Rₛₕ is the sheet resistance of the p⁺-Ge. R_{c} is a major component of the external resistance (Rₑₓₜ) in the transistors.

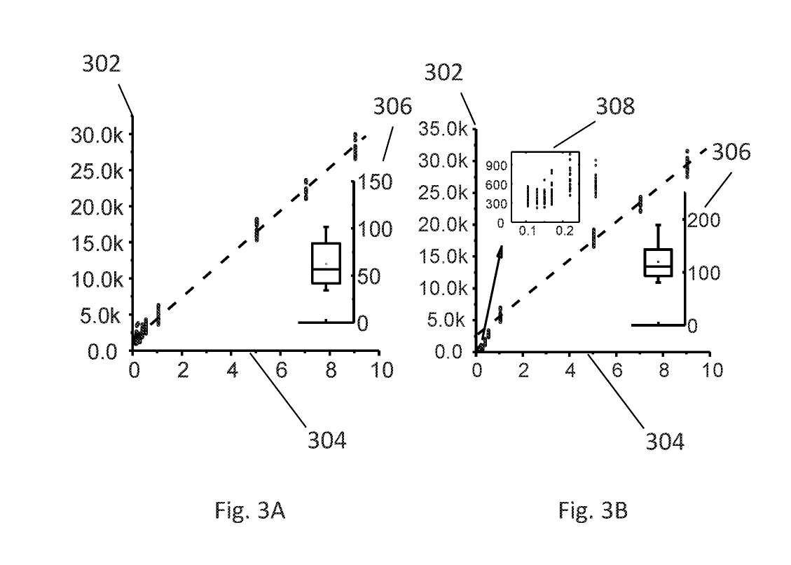

In FIGS. 3A and 3B, the Ti and NiGe contacts are compared on Fin-TLM. FIG. 3A shows results for Ti/p-Ge and FIG. 3B shows results for NiGe. Fin-TLM resistance is plotted on axis 302 versus electrode spacing on axis 304. R_{c} results are indicated at insets 306. For each condition, 20 sets of data were measured. On one hand, the median R_{c} value of the Ti/p-Ge from Fin-TLM is close to that from CTLM. On the other hand, problems are observed for the NiGe: 1) contrary to the CTLM results, the R_{c} of the NiGe/p-Ge is higher than the Ti/p-Ge; 2) the resistances of the NiGe Fin-TLMs with small spacing fall out of the linear resistance-spacing trend, as shown in magnification view 308 (the fit line for the NiGe data excludes the low spacing data that depart from the linear trend). We speculate that a short circuit is created for those small-spacing TLMs due to Ni diffusion. Recently, a Ni diffusion induced large leakage from the Ge n⁺/p shallow junction was observed.

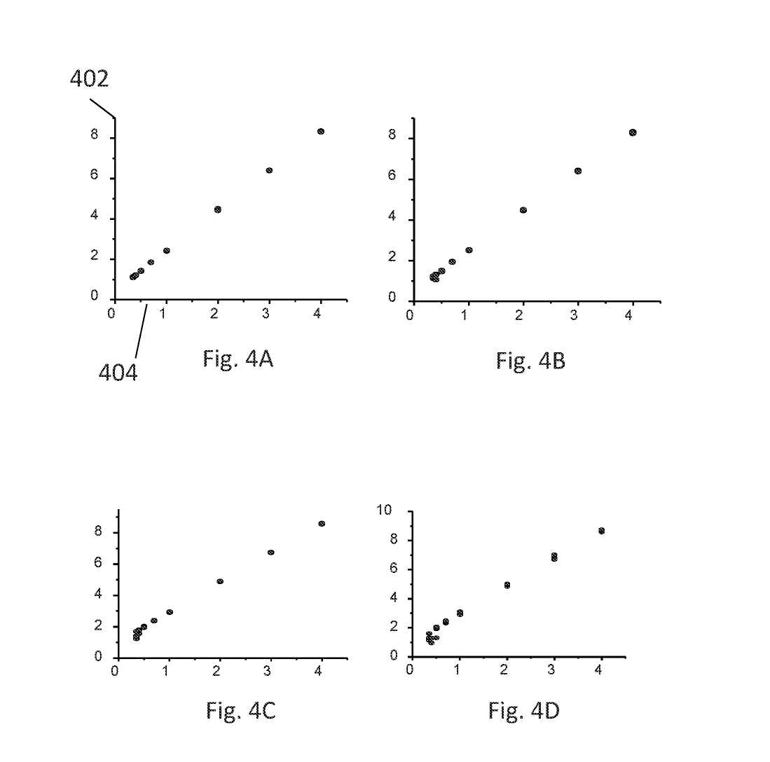

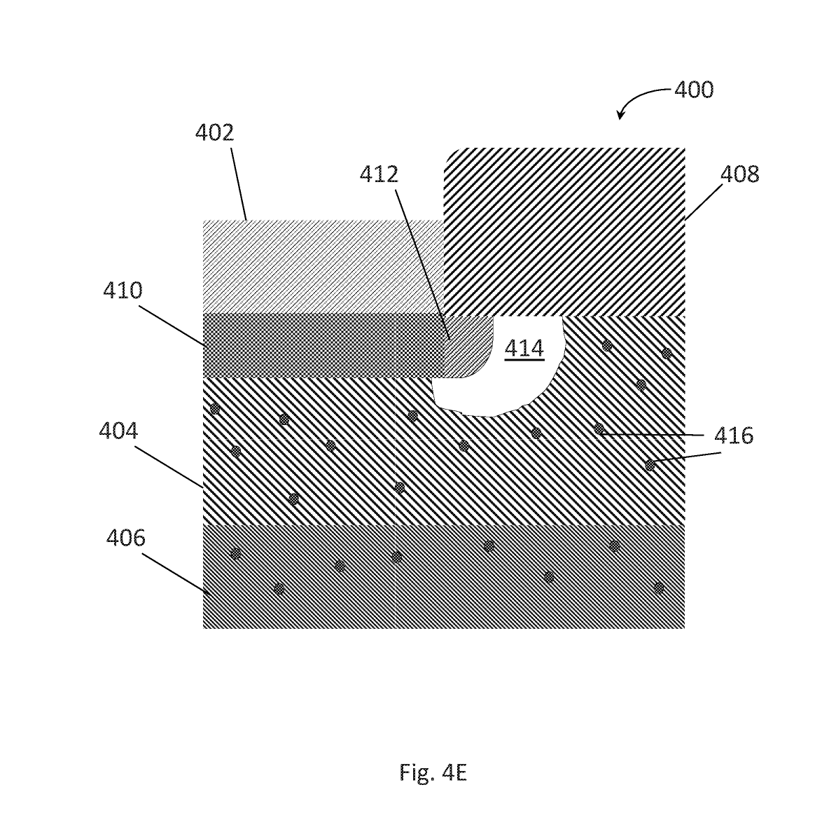

FIGS. 4A-4D show CTLM data for NiGe/p-Ge samples. Each graph plots CTLM resistance (Ω) along axis 402 and electrode spacing (pm) along axis 404. FIG. 4A shows results for as-deposited NiGe/p-Ge, FIG. 4B shows results after a 450° C. anneal for 5 min., FIG. 4C is for the same anneal temperature for 30 min., and FIG. 4D is for a 500° C. anneal for 5 min. The short circuit phenomenon is not reflected in the as deposited NiGe/p-Ge CTLM data of FIG. 4A. Apart from the structure difference, a major difference between the Fin-TLM and the CTLM is the thermal budget in the post-contact processing: the Fin-TLM had seen two W CVD steps at ˜425° C. and a H₂ sintering step at 400° C. for 20 min; the CTLM was free of the aforementioned steps, and the highest processing temperature was at ˜370° C. To find out if it is the thermal process that causes the short circuit, an RTP experiment in N₂ was performed on the NiGe/p-Ge CTLM samples. As shown in FIG. 4B-4D, a 450° C. 5 min anneal could already degrade the NiGe/p-Ge CTLM, while an increase of either the anneal temperature or the duration worsens the situation. Like the Fin-TLM, only small-spacing CTLMs suffer from a short circuit, which is believed to be a thermally driven event.

Note that the short circuits of the TLMs originate from such a thin Ni film as 10 nm. FIG. 4E is a schematic cross-sectional view of a device 400, which shows problems related to NiGe. The device 400 includes a NiGe contact area 402, a doped area 404 under the contact area 402, a substrate 406 under the doped area 404, and an oxide area 408 over the doped area 404 and adjacent to the contact area 402. The contact area 402 includes a Ge consumption area 410 where excess Ge has been incorporated in the contact area 404. The contact area 402 also includes an extension area 412 where the NiGe has extended beneath the oxide area 408. The device 400 also includes a void area 414 beneath the oxide area 408 between the contact area 402 and the doped area 404. The doped area 404 and the substrate 406 include Ni atoms and ions 416, schematically shown as dots. Note that the problems exemplified by the Ge consumption area 410, the extension area 412, and the void area 414 will affect TLMs with all spacing, while the Ni diffusion exemplified by Ni atoms and ions 416 is directly related to the short circuit problem for the small-spacing TLMs. Ni and Cu are two fastest diffusion impurities in Ge. They could precipitate at the lattice dislocations or other crystal defects and form local conductive media. For the small-spacing TLMs, the two NiGe electrodes are close and therefore there is a higher chance for those local precipitated defects to form conductive paths. Therefore, considering the short channel in the modern devices and the standard thermal budget in processing, the NiGe and Cu₃Ge contacts should not be applied into the p-Ge based transistors, despite their low ρ_{c} on p-Ge. The problems illustrated in FIG. 4E create inaccuracy of TLM fitting and ρ_{c} extraction for germanide contacts.

Ni-Ge reaction starts at 250° C., and gets agglomerated at 500° C. In contrast, Ti thin film could remain unreacted on Ge substrate till ˜450° C.; from 450° C., Ti intermix with Ge, and the first clear Ti—Ge alloy phase occurs at ˜550° C. Therefore, Ti is a better candidate for the source/drain contacts in p-Ge devices, considering its low ρ_{c} on p-Ge, its thermal stability with Ge, and its O scavenging property.

### Multi-Pulse Laser for B Activation

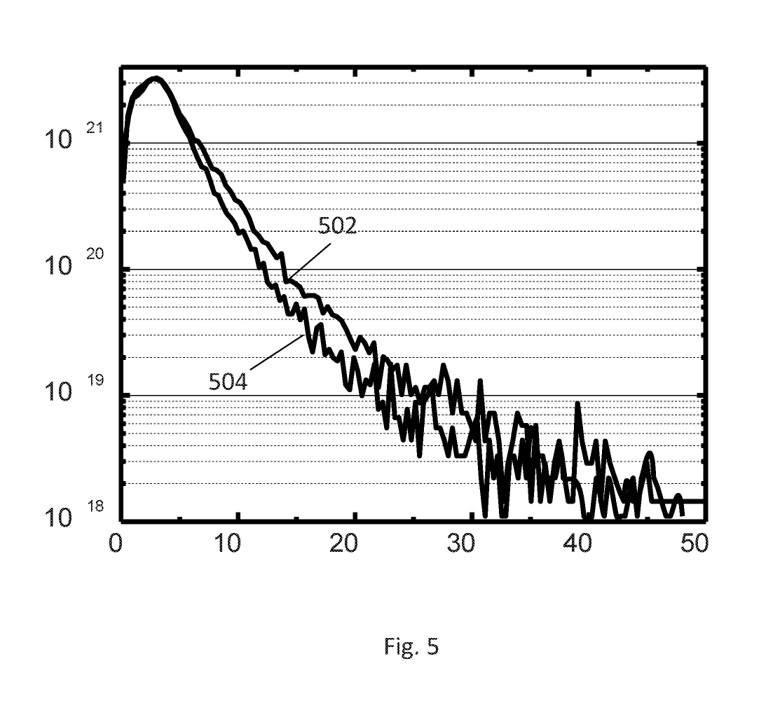

In this work, a low-energy Ge PAI and B I/I was applied, and the SIMS B profiles in the CTLM samples are shown in FIG. 5. In FIGS. 2A and 2B, the Ti/p-Ge contacts with different B activation methods are compared: ρ_{c}-wise, RTP>SP laser>MP laser. According to the field emission theory,

$${ρ}_{c} ∝ exp ( C \frac{{ϕ}_{b}}{\sqrt{{N}_{a}}} ) \qquad ( 2 )$$

where C is a constant, Φ_{b} is the Schottky barrier height, and Nₐ is the active B concentration in our case. The ρ_{c} results in FIG. 2A indicate the highest Nₐ by the MP laser.

As shown in FIG. 2B, the Rₛₕ is high for both the RTP and the laser annealed samples. Particularly, for the multi-pulse laser annealed samples, a high Nₐ (according to low ρ_{c}) but low mobility could be inferred. This is probably due to the low-energy PAI used in this work. In principle, the PAI is an effective technique for Ge p⁺/n shallow junction formation: it prevents the B channeling effect, adds the abruptness of the B profile and improves the B Activation. However, it has been shown that the shallowly preamorphized Ge, where the amorphous/ crystalline Ge interface is within the B projected range, suffers from an imperfect Ge recrystallization during the B I/I and thereby defects form in the p⁺ Ge. These B I/I induced defects could not be fully removed by either an ˜600° C. RTP or a nanosecond laser anneal.

This problem with PAI leads to a dilemma: a low-energy PAI is insufficient and causes a low hole mobility, but a high-energy PAI is incompatible with the downscaled devices—the Ge recrystallization on fin structures is even much more difficult. To achieve simultaneously a shallow Ge p⁺/n junction, a high hole mobility, and a high B active concentration, cryogenic B I/I without PAI and insitu B doped Ge epitaxy might be two promising doping solutions. The MP laser anneal applied in this work could be applied to further boost the B activation and ensure an ultralow ρ_{c} on the p⁺ Ge.

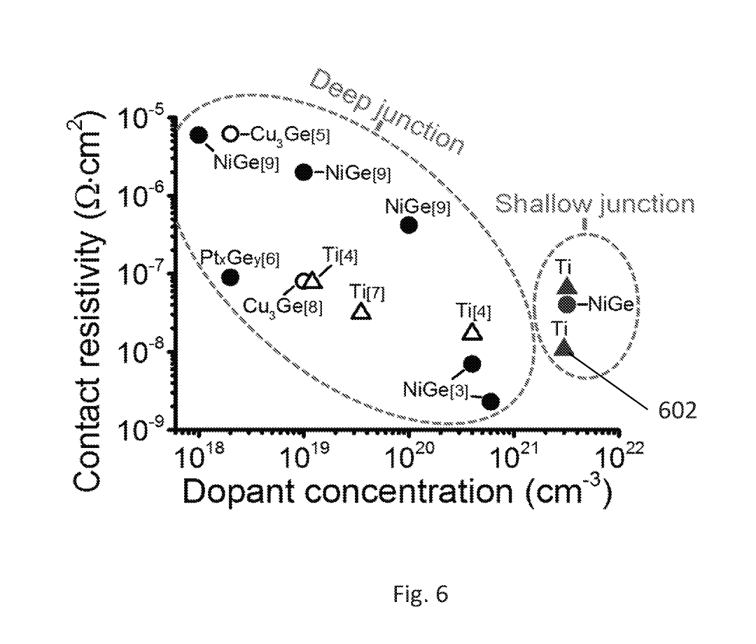

To our knowledge, both shallow p⁺/n Ge formation and the Ti/p⁺Ge ρ_{c} on shallow junction have rarely been studied. As summarized in FIG. 6, all of the previously reported ρ_{c} studies on p⁺Ge were based on junctions deeper than 100 nm. In FIG. 6, circular symbols are germanide contacts, triangular symbols are pure metal contacts, hollow symbols are plotted based on active dopant concentration, and solid symbols are plotted based on physical dopant concentration. These results show higher dopant concentration at similar contact resistivity compared to prior results, with the Ti/p-Ge result shown at 602 having contact resistivity of 1.1×10⁻⁸ Ω·cm².

### CONCLUSIONS

NiGe/p⁺ Ge contacts show low thermal stability that cannot survive the thermal budget of the standard manufacturing process. In contrast, Ti/p⁺Ge contacts show adequate stability and low contact resistance, and therefore suit better the p-Ge devices. A contact resistivity of 1.1×10⁻⁸ Ω·cm², less than the contact resistivity of about 3×10⁻⁸ Ω·cm² observed for Ni—Ge contacts, is achieved for Ti contacts on the multi-pulse laser annealed p⁺ Ge substrate. Use of multi-pulse laser annealing enables activation of high concentrations of dopants without applying an unacceptable thermal budget because the thermal energy transferred to the substrate by each laser pulse is minimal. The short laser pulse imparts kinetic energy to dopants, and a minimal amount of thermal energy to the dopants and surrounding atoms, and duration between pulses is selected to allow the thermal energy to radiate out of the substrate before the next pulse arrives. In this way, the time-temperature profile of the substrate does not give rise to the problems attending prior contact processes.

While the foregoing is directed to certain embodiments, other and further embodiments may be devised without departing from the basic scope of this disclosure.

1. A method of processing a substrate, comprising:
forming a germanium structure on a substrate by epitaxy;
doping the germanium structure with a p-type dopant to form a doped germanium structure;
forming an annealed structure by delivering one or more laser pulses to each of a plurality of target zones of the doped germanium structure, wherein the laser pulses are separated by a duration of at least 200 msec; and
forming a titanium structure on the annealed structure.

2. The method of claim 1, wherein the p-type dopant is boron.

3. The method of claim 1, wherein each of the one or more laser pulses has a duration less than about 50 nsec.

4. The method of claim 1, wherein doping the germanium structure is performed by amorphizing the germanium structure and then implanting p-type ions into the amorphized germanium structure.

5. A method of processing a substrate, comprising:
forming a p-doped epitaxial germanium structure on a substrate;
annealing portions of the p-doped epitaxial germanium structure by exposing all areas of the annealed portions to multiple pulses of laser radiation; and
forming a titanium structure on the p-doped epitaxial germanium structure.

6. The method of claim 5, wherein forming the p-doped epitaxial germanium structure comprises:
disposing the substrate in an epitaxy chamber;
delivering a gas mixture comprising a germanium precursor and a p-type dopant precursor to the epitaxy chamber; and
heating the substrate to a temperature of at least 500° C.

7. The method of claim 6, wherein the p-type dopant is boron.

8. The method of claim 7, further comprising, after forming the p-doped epitaxial germanium structure on the substrate, annealing the substrate by delivering one or more laser pulses to each of a plurality of target zones of the substrate in succession.

9. The method of claim 8, wherein each of the one or more laser pulses has a duration less than about 50 nsec.

10.-13. (canceled)

14. A semiconductor device, comprising:
an activated p-doped epitaxial germanium structure; and
a titanium structure in direct contact with the activated p-doped epitaxial germanium structure.

15. The method of claim 1, wherein the titanium structure has a dimension of 5 nm or less.

16. The device of claim 14, wherein the titanium structure has a dimension of 5 nm or less.

17. The method of claim 1, wherein the titanium structure has a contact resistance of 3×10-8 Ω·cm2 or less.

18. The device of claim 14, wherein the titanium structure has a contact resistance of 3×10-8 Ω·cm2 or less.

19. The method of claim 1, wherein the doping the germanium structure with a p-type dopant is performed at a temperature between about 200K and about 300 K.

20. The method of claim 19, wherein the p-type dopant is boron.

21. The method of claim 19, wherein each of the one or more laser pulses delivered to the plurality of target zones has a duration less than about 50 nsec.

22. The method of claim 21, wherein the germanium structure is formed between two dielectric isolation features on the substrate.
